(19) United States
(12) Patent Application Publication
(10) Pub. No.: US 2026/0332176 A1
(43) Pub. Date: Oct. 22, 2026

(54) HIGH-SPEED DATA TRANSMITTER

(71) Applicant: Marvell Asia Pte Ltd, Singapore (SG)

(72) Inventors: Xinping Yang, San Jose, CA (US); Peng Liu, Fremont, CA (US); Zhendong Guo, San Jose, CA (US); Zhipeng Li, Fremont, CA (US)

(73) Assignee: Marvell Asia Pte Ltd, Singapore (SG)

(21) Appl. No.: 19/529,387

(22) Filed: Feb. 4, 2026

Related U.S. Application Data
(60) Provisional application No. 63/755,200, filed on Feb. 6, 2025.

(51) Int. Cl. H04B 1/04; H03F 3/45; H03K 17/687; H03M 1/66

(52) U.S. Cl. CPC H04B 1/0475; H03F 3/45475; H03K 17/6871; H03M 1/66; H04B 2001/0433

(57) ABSTRACT

A current mode driver for a high-speed transmitter output includes a first stage for converting an input current of the current mode driver to a voltage proportional to the input current; and a second stage connected to the first stage for linearly amplifying the input current to generate an output current.

### PRIORITY APPLICATION

This patent application claims priority to and/or the benefit of U.S. Provisional Application No. 63/755,200 entitled, “Innovative Structure for 224G High-speed Transmitter,” filed on Feb. 6, 2025, which is hereby incorporated by reference in its entirety.

### BACKGROUND

Given the ever-increasing demand for bandwidth to satisfy requirements of artificial intelligence (AI) systems, 100 gigabit (Gb)/lane connectivity is transitioning to 200Gb/lane connectivity to enable 1.6 terabit per second (16T) Ethernet. Enabling robust operation at this data transmission necessitates resolution of numerous technical challenges, such as component bandwidth and signal integrity improvements in cables, connectors, and packages. Achieving a 200Gb/lane objective requires power- and area-efficient approaches. A 224Gb/second (224G) transceiver is a critical component for enabling this level of connectivity.

### BRIEF DESCRIPTION OF THE DRAWINGS

Embodiments will be readily understood by the following detailed description in ‎conjunction with the accompanying drawings. To facilitate this description, like reference ‎numerals designate like structural elements. Embodiments are illustrated by way of ‎example, and not by way of limitation, in the figures of the accompanying drawings.

FIG. 1A illustrates a block diagram of processor module including an AI server processor, according to some embodiments of the disclosure.

FIG. 1B illustrates a block diagram of die-to-die clocking and serializer-deserializer (SerDes) circuitry of the processor module of FIG. 1A, according to some embodiments of the disclosure.

FIG. 2 illustrates a block diagram of an exemplary 4-lane 224G SerDes transceiver, according to some embodiments of the disclosure.

FIG. 3 illustrates a block diagram of the architecture of a transmission (TX) circuit that may be implemented in the SerDes module of FIG. 2, according to embodiments of the disclosure.

FIG. 4 illustrates a schematic block diagram of TX driver circuitry that may be implemented in the TX circuit of FIG. 3, according to embodiments of the disclosure.

FIG. 5 illustrates a more detailed schematic block diagram of the TX driver circuit of FIG. 4, according to some embodiments of the disclosure.

### DETAILED DESCRIPTION

### Overview

In accordance with features of embodiments described herein, an innovative 224G transmitter deploys a current mode, rather than a voltage mode, driver to support high speed operation. The 224G transmitter described herein supports high amplitude, achieves significant linearity, and provides competitive power consumption versus other transmitter architectures. The current mode driver is implemented in two stages, including a first stage comprising a transimpedance amplifier (TIA) and a second stage comprising a push-pull buffer for amplifying input current from a digital-to-analog circuit (DAC) of the transmitter.

### Exemplary AI server processor

An AI server processor is a high-performance integrated circuit designed to execute compute-intensive workloads, such as AI inference, training, and large-scale server operations. Such AI server processors typically include several common components, including a scalable core complex, a die-to-die interconnect (I/O subsystem), PLLs, memory hierarchy, and power and thermal management.

A scalable core complex may include a plurality of processing cores arranged in a scalable architecture to support varying performance and power requirements. Each core may include vector or matrix acceleration units optimized for AI workloads, along with general-purpose execution pipelines for server tasks. The cores may be interconnected through a high-bandwidth on-die fabric, enabling low-latency communication and dynamic workload distribution.

A die-to-die interconnect, or I/O subsystem, may include high-speed die-to-die interfaces for connecting multiple processor dies within a package or across chiplets, which interfaces may utilize advanced signaling techniques to achieve low latency and high throughput for memory access and inter-processor communication. The I/O subsystem often supports coherent protocols to maintain data consistency across dies.

PLL circuits may be employed to generate and synchronize clock signals for the processor cores and I/O interfaces. Multiple PLLs may be distributed across the die to provide localized clock domains, ensuring timing integrity for high-speed links and scalable core clusters. PLLs may also enable dynamic frequency scaling to optimize performance and power efficiency.

Memory hierarchy may include integrated cache structures (e.g., L1, L2, and shared L3) for reducing memory access latency. External memory controllers may be provided for supporting DDR, HBM, or other high-bandwidth memory technologies for large-scale data processing.

Power and thermal management may include on-die power delivery networks and voltage regulators for fine-grained control of core and I/O power states. Thermal sensors and dynamic throttling mechanisms may be provided to maintain operational reliability under heavy workloads.

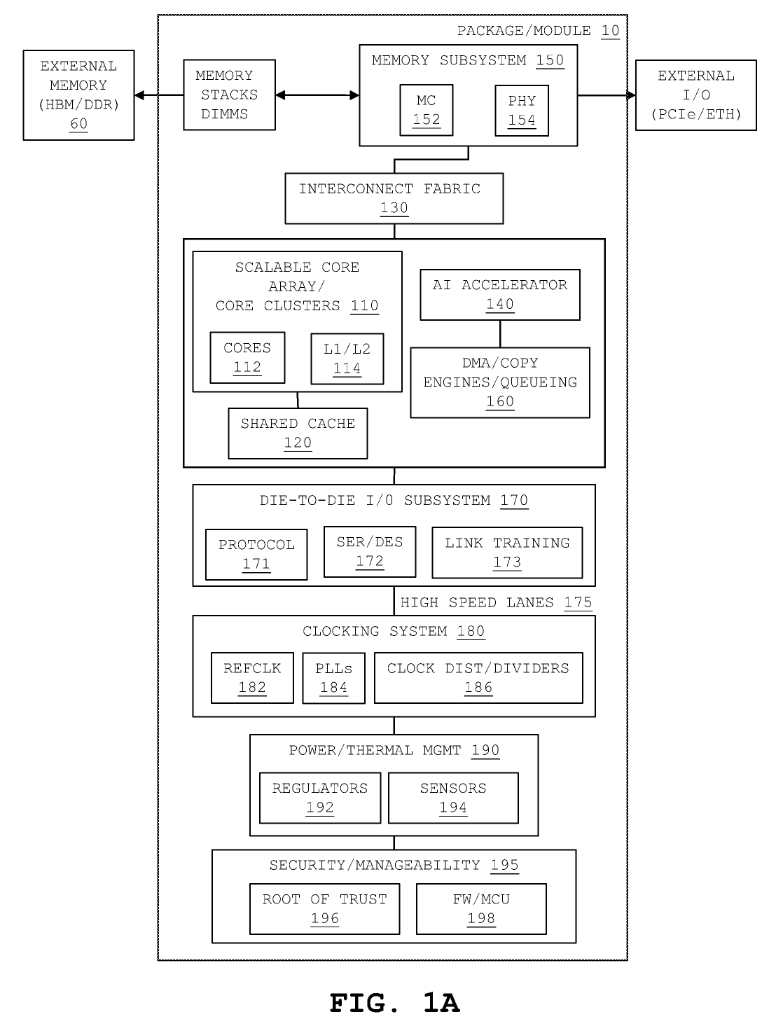

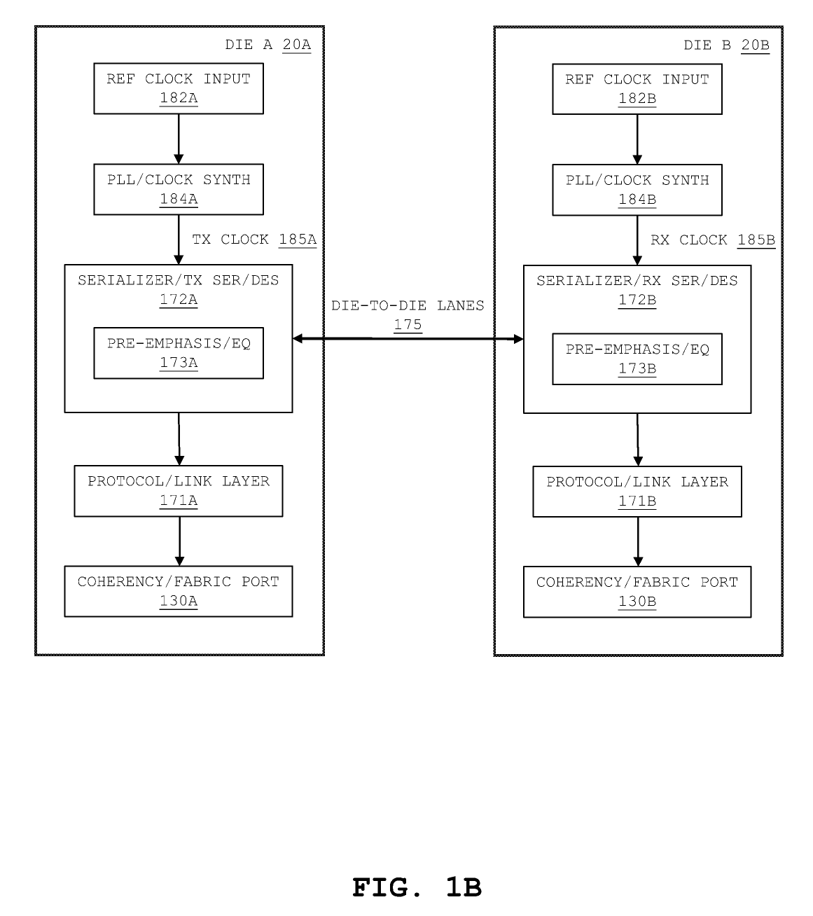

FIG. 1A illustrates a processor module 10 including an AI server processor 100 configured for scalable compute throughput and multi-die expansion. Processor 100 includes scalable core array 110 coupled to interconnect fabric 130. Scalable core array 110 includes a plurality of processor cores 112 arranged as one or more core clusters, core tiles, or core complexes, with private or semi-private cache resources such as L1/L2 cache 114. Interconnect fabric 130 provides communication among scalable core array 110, shared cache 120, AI accelerator 140, memory subsystem 150, and die-to-die I/O subsystem 170. Shared cache 120 provides a shared last-level cache (LLC), system-level cache (SLC), or another shared caching structure supporting reduced off-die bandwidth demand and reduced average memory access latency for workloads including AI inference, AI training, and server processing.

AI accelerator 140 includes one or more fixed-function or programmable engines that execute matrix, vector, or tensor operations, with data paths supporting parallel multiply-accumulate (MAC) operations and optional sparsity, quantization, or mixed-precision processing. DMA/copy engines 160 support movement of data among shared cache 120, memory subsystem 150, AI accelerator 140, and peripheral interfaces, with queueing structures and command processors supporting asynchronous transfers, scatter-gather operations, and memory-to-memory copy operations.

Memory subsystem 150 includes one or more memory controllers 152 and one or more memory physical interfaces (PHYs) 154 that couple processor 100 to external memory 60. External memory 60 includes high-bandwidth memory (HBM), double data rate memory (DDR), or another memory technology. Memory controller 152 supports scheduling, refresh, ordering rules, and quality-of-service (QoS) arbitration, while memory PHY 154 supports high-speed signaling, training, and calibration for memory channels.

Die-to-die I/O subsystem 170 provides high-speed communication between processor 100 and at least one additional die or chiplet within module 10. Die-to-die I/O subsystem 170 includes protocol layer 171, serializer/deserializer circuitry (SerDes) 172, and link training/equalization circuitry 173. Protocol layer 171 supports packetization, ordering, flow control, and optional coherency semantics for transactions that traverse die-to-die lanes 175. Link training/equalization circuitry 173 supports lane initialization, deskew, equalization setting selection, margining, and retry behavior. Die-to-die lanes 175 support high-throughput point-to-point signaling implemented as parallel single-ended lanes, differential lanes, or a combination thereof, with optional forward error correction (FEC) and cyclic redundancy check (CRC) protection. In some embodiments, die-to-die I/O subsystem 170 supports coherent communication that maintains cache coherence across shared cache 120 instances distributed across multiple dies, with protocol layer 171 exchanging coherence messages and associated data payloads over die-to-die lanes 175.

Clocking system 180 supports timing generation and distribution for scalable core array 110, interconnect fabric 130, memory subsystem 150, and die-to-die I/O subsystem 170. Clocking system 180 includes reference clock source 182, one or more phase-locked loops (PLLs) 184, and clock distribution/divider circuitry 186. Reference clock source 182 provides a reference frequency derived from an oscillator, board clock, or package-distributed clock. PLL 184 generates one or more synthesized clocks having frequencies and phases suitable for core clock domains, fabric clock domains, memory clock domains, and I/O clock domains. PLL 184 provides frequency multiplication and optional fractional synthesis, jitter filtering, and phase alignment to support timing closure for high-speed interfaces. Clock distribution/divider circuitry 186 distributes synthesized clocks to clock domains and may include dividers, multiplexers, glitchless clock switching logic, clock gating cells, and clock-domain-crossing (CDC) support circuitry. In some embodiments, clocking system 180 includes separate PLL instances 184 assigned to distinct domains, including a core PLL instance supporting scalable core array 110 and an I/O PLL instance supporting die-to-die I/O subsystem 170, with independent voltage and frequency scaling per domain.

Power and thermal management subsystem 190 supports power delivery and reliability for processor 100. Subsystem 190 includes voltage regulation circuitry 192 and sensor circuitry 194. Voltage regulation circuitry 192 includes integrated voltage regulators, low-dropout regulators, switched-capacitor regulators, or digitally controlled external regulator interfaces. Sensor circuitry 194 includes temperature sensors, voltage monitors, current monitors, and performance counters used to enforce power limits and thermal limits. In some embodiments, subsystem 190 controls dynamic voltage and frequency scaling (DVFS) via control of PLL 184 and domain voltage rails, with policies that maintain performance targets while satisfying thermal and power constraints.

Security/manageability subsystem 195 supports platform security and operational management. Subsystem 195 includes root-of-trust circuitry 196 and management controller or firmware processor 198. Root-of-trust circuitry 196 supports secure boot, key storage, attestation, and cryptographic primitives. Management controller 198 supports telemetry, debug access controls, and lifecycle management functions including configuration of die-to-die I/O subsystem 170, configuration of clocking system 180, and configuration of power/thermal management subsystem 190.

FIG. 1B illustrates a die-to-die lane clocking arrangement implemented by die 20A coupled to die 20B through die-to-die lanes 175. Die 20A includes reference clock input 182A coupled to PLL 184A. PLL 184A generates transmit (TX) clock 185A that drives serializer/TX SerDes 172A. Serializer/TX SerDes 172A transmits serialized data over die-to-die lanes 175 with link conditioning via equalization circuitry 173A. Die 20B includes reference clock input 182B coupled to PLL 184B. In an embodiment, PLL 184B generates one or more receive (RX) clocks 185B that support sampling and recovery for deserializer/RX SerDes 172B. In another embodiment, deserializer/RX SerDes 172B includes clock-data recovery (CDR) within circuitry 173B that recovers sampling phase from transitions embedded in lane signaling, with PLL 184B providing a low-jitter local reference used for CDR loop stability or retiming. Protocol/link layer 171A and protocol/link layer 171B perform link initialization, lane alignment, deskew, and integrity checks, then present transactions to coherency/fabric ports 130A and 130B. Arrangement supports scalable multi-die construction by replicating die-to-die instances and scaling lane counts, with PLL instances supporting clock-domain isolation and jitter management for increasing link speeds.

### Exemplary 224G SerDes transceiver

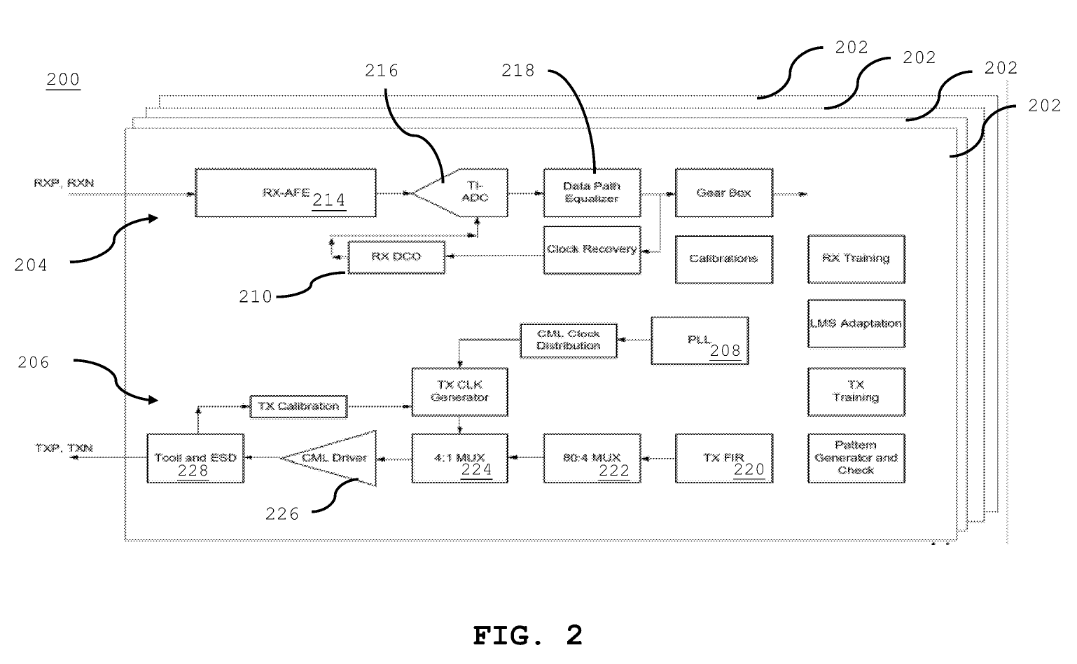

FIG. 2 illustrates a block diagram of a 224G SerDes transceiver 200 according to features of embodiments described herein. As shown in FIG. 2, SerDes transceiver 200 comprises four lanes 202, each of which may operate independently of the others. Additionally, each of the lanes 202 may be able to pair different receivers (RXs), such as RX 204, and transmitters (TXs), such as TX 206, across the lanes as a single port to improve package break out and alignment with printed circuit board (PCB) routes in high lane density applications. An adaptable, reconfigurable architecture may be used to enable data rate flexibility, along with power saving modes. Each TX 206 is implemented with an adjacent PLL 208 with the option to share the PLL across two lanes. Each RX 204 operates independently, with clock generation through a lane-dedicated multi-mode digitally controlled oscillator (DCO) 210. A common block distributes voltage and current references across lanes 202 and includes a temperature sensing module that supports temperature tracking functions needed to reduce performance variation over a wide temperature range. An analog-front-end (AFE) 214 of RX 204 includes a highly conﬁgurable wide-band continuous time linear equalizer (CTLE) that equalizes a wide range of loss across various data rates. The CTLE output is quantized through a time-interleaved analog-to-digital converter (TI-ADC) 216 to enable a digital signal processor (DSP) 218 for providing digital equalization and performance monitoring for the receiver 204.

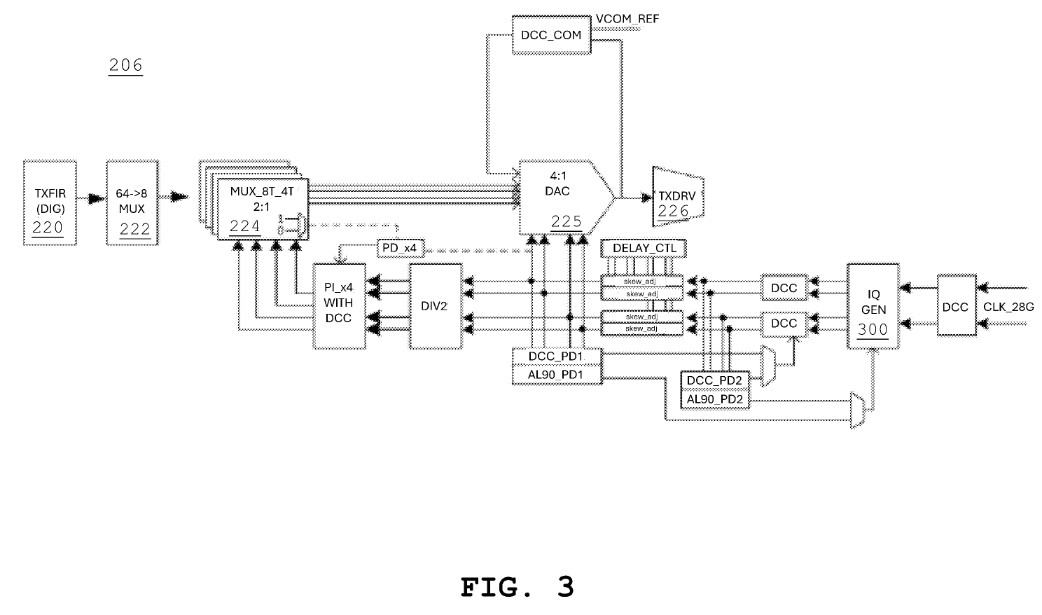

As previously noted, PLL 208, which in certain embodiments is implemented as a low-jitter analog PLL, generates the clock for each TX 206. The TX data path consists of a finite impulse response (FIR) filter 220 followed by a data serializer and high-speed MUX stages 222, 224. An 8-bit digital-to-analog converter (DAC) 225 (FIG. 3) converts the data to analog domain, where it is buffered with a high-bandwidth current-mode-logic (CML) driver 226. An output of CML driver 226 is connected to an output network 228 comprising a T-coil circuit.

### Exemplary 224G SerDes transmitter circuit

Referring now also to FIG. 3, in one embodiment, digital equalization of TX 206 is provided by FIR filter 220, which may be implemented as a 10-tap FIR filter, with 6 taps positioned around the main tap and two 2-tap banks that can cover a range of up to 30 unit interval (UI). An 8-bit DAC-based transmitter with 6 bits binary and 2 thermometric bits uses a differential input clock of up to 28GHz generated from an inductor-capacitor PLL (LCPLL). Resonant CML stages distribute the clock to the TX, providing filtering for broadband noise, thereby improving clock jitter. An IQ generator 300 converts an incoming clock signal to quadrature phases and is assisted by a phase detection and control loop for calibration and tracking. The quadrature clocks drive a final 4-to-1 MUX, as well as the clock generation circuitry for the 64-to-4 serializer. The serializer consists of a 4-to-1 shift register and two stages of 2-to-1 MUXes. A timing detection circuit is implemented to maximize interface timing for the last 2-to-1 MUX interface of the serializer.

### Exemplary CML driver for 224G SerDes transmitter circuit

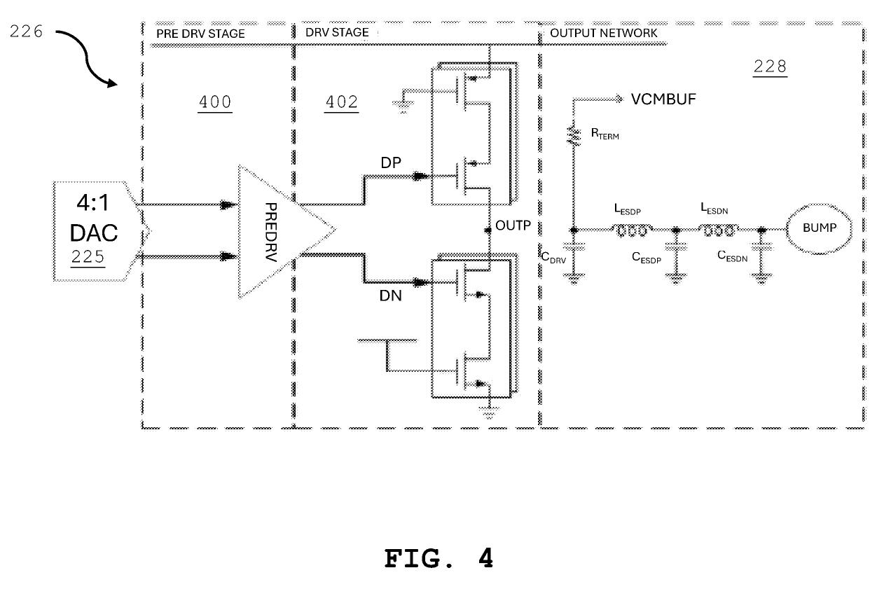

As better illustrated in FIG. 4, as noted above with reference to FIGS. 2 and 3, in accordance with features of embodiments described herein, TX 206 includes a 2-stage current mode driver 226. A first stage 400 is provided for converting 4-phase interleaved DAC current into voltage proportional to the current. A second stage 402 comprises a push-pull buffer for mirroring the current to the driver output. Output network 228 comprises an optimized T-coil and inductive network along with a tuned resistive termination providing impedance matching as well as bandwidth boost by isolating driver 226 from electrostatic discharge (ESD) and bump loading. As a result, TX 206 is a high performance and power efficient transmitter with current mode driver that achieves 0.86pJ/b power efficiency at 212.5Gb/s.

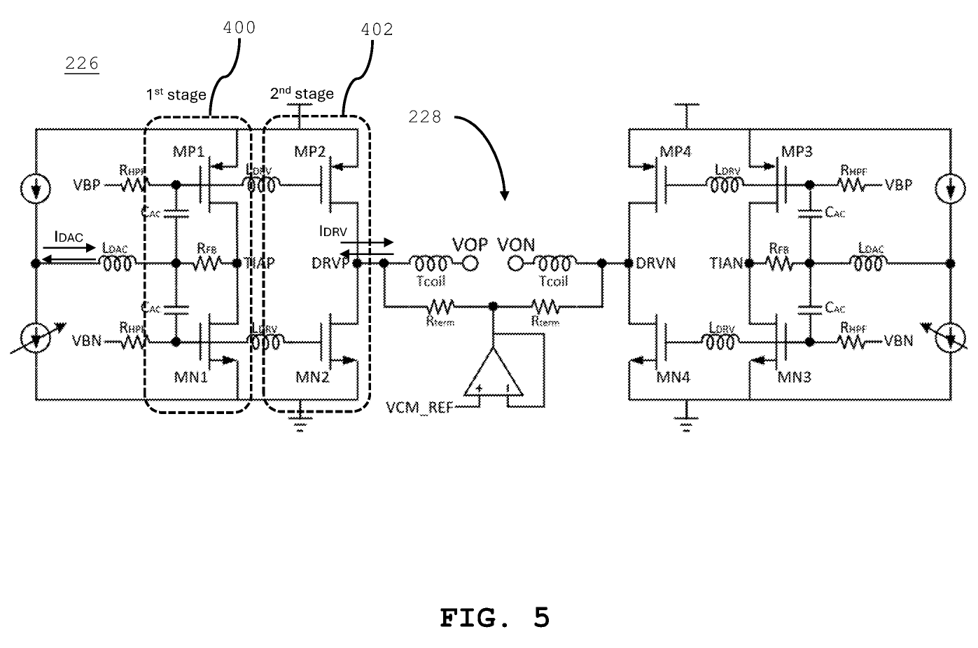

FIG. 5 illustrates a more detailed schematic block diagram of CML driver 226. As previously noted, and as illustrated in FIG. 5, driver 226 is a current mirror based driver comprising two stages 400, 402. First stage 400 comprises a transinductance amplifier (TIA) for converting full rate current from DAC 225 (FIGS. 3 and 4) IDAC to a voltage. Second stage 402 comprises a push-pull buffer to mirror the current to the output stage 404 as IDRV. The ratio of IDAC to IDRV can be adjusted properly for different requirements. VBP and VBN are bias voltages to set driver bias current and VCM of nodes DRVP and DRVN. Inductors LDRV and LDAC are provided for internal bandwidth extension due to parasitic effects.

RHPF and CAC together form a high-pass filter (HPF) that allows the high-speed current IDAC to pass through the TIA stage with the proper bias condition determined by VBP/VBN. The corner frequency of this HPF is designed to be 20kHz (with some programmability), in order to support broadband data rate from 10Gbps to 226.875Gbps. RFB is an essential element of the TIA stage, and with a proper value it can also help to track the linearity between the 1^{st} and 2^{nd} stage. It is usually designed to be around 60ohms. LDRV is around 40pH and LDAC is around 30pH. VCM_REF is the reference voltage for the driver common-mode buffer, it is by default set to be half of the AVDD value.

In a particular implementation, at a node DRVP, a prescribed voltage differential is needed to drive the next stage. To achieve this, the current at node DRVP (IDRV) must be a certain amplitude. Accordingly, the purpose of driver 226 is to amplify the ultra-high speed DAC current (IDAC) linearly and by a multiple (e.g., 2x) between first and second stages 400, 402.

In an example embodiment, IDAC is 5mA and IDRV should be 10mA to achieve a necessary 900mV voltage differential at node DRVP; therefore, driver 226 must implement a 2x linear amplification. It will be recognized, however, that relative sizes of devices included in first stage 400 and second stage 402, particularly sizes of transistors MP1, MN1, MP2 and MN2, may be adjusted to enable other ratios as necessary or desired for the particular application. Additionally, it will be noted that multiple push-pull buffers may be cascaded to implement second stage 402 to further amplify the current; however, such amplification may be at the expense of bandwidth and SNDR.

As previously noted, first stage 400 is implemented as a TIA, which converts an input current (i.e., IDAC) to an output voltage proportional to the input current. First stage 400 includes two CACs, each of which function as AC capacitors that block DC signals in combination with large (e.g., at least approximately 10 kilohms) resistors RHPF, and convert IDAC to a voltage swing at gates of a PMOS transistor MP1 and an NMOS transistor MN1. The same voltage swing is applied at gates of a PMOS transistor MP2 and an NMOS transistor MN2. Assuming transistors MP2 and MN2 are approximately twice the size of transistors MP1 and MN2, the current at DRVP (i.e., IDRV) will be approximately two times the amplitude of IDAC.

VBP and VBN are bias voltages for biasing transistors MP2 and MN2 to operate at a point in a saturation region and thereby function as a current source. Resistors RHPF are very large (e.g., over 10K) to set the DC operating point of the devices to operate as current switches.

Driver 226 supports high-speed operation due to the nature of current mode drivers vs. voltage mode drivers. Additionally, internal bandwidth extension is easier to perform with inductors LDRV and LDAC versus distributed source series terminated (SST)-based voltage mode drivers. Driver 226 further supports high amplitude (e.g., over 900 mV peak-to-peak (P-P) with 1.2V AVDD due to small headroom requirement resulting from the need to satisfy only Vdsat-p and Vdsat-n. Driver 226 further achieves optimal linearity, including signal to noise and distortion ratio (SNDR) over 40dB. IDAC can be mirrored to IDRV with very low distortion and dynamic current match (with RFB) for improvement in linearity. Moreover, the predriver stage can be designed with very small devices to save significant power consumption.

### SELECT EXAMPLES

Example 1 provides a current mode driver for a high-speed transmitter output, the driver including a first stage for converting an input current of the current mode driver to a voltage proportional to the input current; and a second stage connected to the first stage for linearly amplifying the input current to generate an output current.

Example 2 provides the current mode driver of example 1, in which the first stage includes a transimpedance amplifier circuit.

Example 3 provides the current mode driver of example 1 or 2, in which the second stage includes a push-pull buffer circuit.

Example 4 provides the current mode driver of any one of examples 1-3, in which the first stage includes a first PMOS transistor and a first NMOS transistor and a feedback resistor.

Example 5 provides the current mode driver of example 4, in which the second stage includes a second PMOS transistor and a second NMOS transistor and in which the second PMOS and second NMOS transistors are biased to operate in a saturation mode.

Example 6 provides the current mode driver of example 5, in which the voltage is applied to gates of the second transistors.

Example 7 provides the current mode driver of example 5 or 6, further including a pre-driver stage, the pre-driver stage including an inductor in series with the input current and resistors in series with bias voltages for biasing operation of the second transistors.

Example 8 provides the current mode driver of any one of examples 5-7, in which the second transistors are larger than the first transistors.

Example 9 provides the current mode driver of example 8, in which the second transistors are approximately twice as large as the first transistors.

Example 10 provides the current mode driver of any one of examples 4-9, in which the first stage further includes capacitors for blocking low frequency current and passing high frequency current.

Example 11 provides the current mode driver of any one of examples 1-10, further including a third stage connected to the second stage, in which the third stage is substantially identical to the second stage.

Example 12 provides the current mode driver of any one of examples 1-11, in which the input current is generated by a current mode digital to analog converter (DAC).

Example 13 provides a high-speed transmitter including a current-mode digital-to-analog converter (DAC); a current mode logic (CML) driver connected to receive a DAC current from the DAC, the CML drive including a first stage for converting the DAC current to a voltage proportional to the DAC current; and a second stage connected to receive the voltage from the first stage, the second stage for linearly amplifying the DAC current based on the voltage to generate an output current, in which an amplitude of the output current includes a multiple of an amplitude of the DAC current; and an output stage connected to receive the output current.

Example 14 provides the high-speed transmitter of example 13, in which the first stage includes a transimpedance amplifier circuit (TIA) and the second stage includes a push-pull buffer circuit.

Example 15 provides the high-speed transmitter of example 14, in which the first stage includes a first PMOS transistor and a first NMOS transistor and a feedback resistor.

Example 16 provides the high-speed transmitter of example 15, in which the second stage includes a second PMOS transistor and a second NMOS transistor and in which the second PMOS transistor and second NMOS transistors are voltage-biased to function as current sources and in which the second transistors are at least two times as large as the first transistors.

Example 17 provides the high-speed transmitter of example 16, further including a pre-driver stage, the pre-driver stage between the DAC and the CML driver, the predriver stage including an inductor in series with the input current and resistors in series with bias voltages for biasing the second transistors.

Example 18 provides an apparatus for driving an output network of a high-speed transmitter, the apparatus including a first stage including a transimpedance amplifier (TIA) for converting an input current to a voltage proportional to the input current, in which the input current is generated by a current mode digital-to-analog converter (DAC) connected to an input of the apparatus; and at least one second stage connected to the first stage, the at least one second stage including a push-pull circuit for linearly amplifying the input current to generate an output current, in which an amplitude of the output current is a multiple of an amplitude of the input current.

Example 19 provides the apparatus of example 18, in which the first stage includes a first pair of MOSFET transistors and the at least one second stage includes a second pair of MOSFET transistors, and in which a size of the second pair of MOSFET transistors is the multiple of a size of the first pair of MOSFET transistors.

Example 20 provides the apparatus of example 19, in which gates of the second pair of MOSFET transistors are connected to receive the voltage and in which the second pair of MOSFET transistors are configured to operate as current sources.

### VARIATIONS AND OTHER NOTES

The detailed description, such as the “Select examples” section, provide various examples of the embodiments disclosed herein.

As used herein, the term “coupled to” or “coupled with” refers to a relationship between electronic components or circuit elements wherein the components are in electronic communication with one another and capable of transmitting and/or receiving electrical signals between them. The term “coupled to” does not require a direct physical or electrical connection between the coupled components. Rather, “coupled to” can encompass arrangements where the components are connected through one or more intervening elements, components, circuits, or transmission paths. For example, a first component may be “coupled to” a second component through intermediate components such as resistors, capacitors, inductors, transistors, logic gates, buses, transformers, or other electronic components, or through intermediate transmission paths, while still maintaining the capability for electronic communication between the first and second components.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well known features are omitted or simplified in order not to obscure the illustrative implementations.

Further, references are made to the accompanying drawings that form a part hereof, and in which are shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed or described operations may be omitted in additional embodiments.

For the purposes of the present disclosure, the phrase “A or B” or the phrase “A and/or B” means (A), (B), or (A and B). For the purposes of the present disclosure, the phrase “A, B, or C” or the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicates that different instances of like objects are being referred to and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art.

The terms “substantially,” “close,” “approximately,” “near,” and “about,” generally refer to being within +/- 20% of a target value as described herein or as known in the art. Similarly, terms indicating orientation of various elements, e.g., “coplanar,” “perpendicular,” “orthogonal,” “parallel,” or any other angle between the elements, generally refer to being within +/- 5-20% of a target value as described herein or as known in the art.

In addition, the terms “comprise,” “comprising,” “include,” “including,” “have,” “having” or any other variation thereof, are intended to cover a non-exclusive inclusion. For example, a method, process, or device, that comprises a list of elements is not necessarily limited to only those elements but may include other elements not expressly listed or inherent to such method, process, or device. Also, the term “or” refers to an inclusive “or” and not to an exclusive “or.”

The systems, methods, and devices of this disclosure each have several innovative aspects, no single one of which is solely responsible for all desirable attributes disclosed herein. Details of one or more implementations of the subject matter described in this specification are set forth in the description and the accompanying drawings.

1. A current mode driver for a high-speed transmitter output, the driver comprising:
a first stage for converting an input current of the current mode driver to a voltage proportional to the input current; and
a second stage connected to the first stage for linearly amplifying the input current to generate an output current.

2. The current mode driver of claim 1, wherein the first stage comprises a transimpedance amplifier circuit.

3. The current mode driver of claim 1, wherein the second stage comprises a push-pull buffer circuit.

4. The current mode driver of claim 1, wherein the first stage comprises a first PMOS transistor and a first NMOS transistor and a feedback resistor.

5. The current mode driver of claim 4, wherein the second stage comprises a second PMOS transistor and a second NMOS transistor and wherein the second PMOS and second NMOS transistors are biased to operate in a saturation mode.

6. The current mode driver of claim 5, wherein the voltage is applied to gates of the second transistors.

7. The current mode driver of claim 5, further comprising a pre-driver stage, the pre-driver stage comprising an inductor in series with the input current and resistors in series with bias voltages for biasing operation of the second transistors.

8. The current mode driver of claim 5, wherein the second transistors are larger than the first transistors.

9. The current mode driver of claim 8, wherein the second transistors are approximately twice as large as the first transistors.

10. The current mode driver of claim 4, wherein the first stage further comprises capacitors for blocking low frequency current and passing high frequency current.

11. The current mode driver of claim 1, further comprising a third stage connected to the second stage, wherein the third stage is substantially identical to the second stage.

12. The current mode driver of claim 1, wherein the input current is generated by a current mode digital to analog converter (DAC).

13. A high-speed transmitter comprising:
a current-mode digital-to-analog converter (DAC);
a current mode logic (CML) driver connected to receive a DAC current from the DAC, the CML drive comprising:
a first stage for converting the DAC current to a voltage proportional to the DAC current; and
a second stage connected to receive the voltage from the first stage, the second stage for linearly amplifying the DAC current based on the voltage to generate an output current, wherein an amplitude of the output current comprises a multiple of an amplitude of the DAC current; and
an output stage connected to receive the output current.

14. The high-speed transmitter of claim 13, wherein the first stage comprises a transimpedance amplifier circuit (TIA) and the second stage comprises a push-pull buffer circuit.

15. The high-speed transmitter of claim 14, wherein the first stage comprises a first PMOS transistor and a first NMOS transistor and a feedback resistor.

16. The high-speed transmitter of claim 15, wherein the second stage comprises a second PMOS transistor and a second NMOS transistor and wherein the second PMOS transistor and second NMOS transistors are voltage-biased to function as current sources and wherein the second transistors are at least two times as large as the first transistors.

17. The high-speed transmitter of claim 16, further comprising a pre-driver stage, the pre-driver stage between the DAC and the CML driver, the predriver stage comprising an inductor in series with the input current and resistors in series with bias voltages for biasing the second transistors.

18. An apparatus for driving an output network of a high-speed transmitter, the apparatus comprising:
a first stage comprising a transimpedance amplifier (TIA) for converting an input current to a voltage proportional to the input current, wherein the input current is generated by a current mode digital-to-analog converter (DAC) connected to an input of the apparatus; and
at least one second stage connected to the first stage, the at least one second stage comprising a push-pull circuit for linearly amplifying the input current to generate an output current, wherein an amplitude of the output current is a multiple of an amplitude of the input current.

19. The apparatus of claim 18, wherein the first stage comprises a first pair of MOSFET transistors and the at least one second stage comprises a second pair of MOSFET transistors, and wherein a size of the second pair of MOSFET transistors is the multiple of a size of the first pair of MOSFET transistors.

20. The apparatus of claim 19, wherein gates of the second pair of MOSFET transistors are connected to receive the voltage and wherein the second pair of MOSFET transistors are configured to operate as current sources.
